(19) United States
(12) Patent Application Publication
(10) Pub. No.: US 2025/0006259 A1
(43) Pub. Date: Jan. 2, 2025

(54) SEMICONDUCTOR DEVICE, OPERATING METHOD OF THE SEMICONDUCTOR DEVICE, AND METHOD OF MANUFACTURING THE SEMICONDUCTOR DEVICE

(71) Applicant: SK hynix Inc., Icheon (KR)

(72) Inventor: Jae Yeon Lee, Icheon-si (KR)

(21) Appl. No.: 18/476,939

(22) Filed: Sep. 28, 2023

(30) Foreign Application Priority Data
Jun. 27, 2023 (KR) 10-2023-0082701

(51) Int. Cl. G11C 13/00; H10B 63/00; H10N 70/00

(52) U.S. Cl. CPC G11C 13/0028; G11C 13/0026; H10B 63/84; H10N 70/043

(57) ABSTRACT

A semiconductor device may include a voltage generation circuit configured to generate a driving voltage in response to a voltage control signal, a row decoder configured to select at least one word line, among a plurality of word lines, in response to a row address signal, and configured to apply the driving voltage to the selected word line, a column decoder configured to select at least one bit line, among a specific bit line and a plurality of bit lines, in response to a column address signal and a control circuit configured to generate the voltage control signal, the row address signal, and the column address signal, and configured to control the column decoder to select the specific bit line and at least one of the plurality of bit lines in a firing operation.

### CROSS-REFERENCE TO RELATED APPLICATION

This application claims priority under 35 U.S.C. § 119 to Korean Patent Application No. 10-2023-0082701 filed on Jun. 27, 2023, which is incorporated herein by reference in its entirety.

### BACKGROUND

### 1. Technical Field

Embodiments relate to a three-dimensional cross-point memory structure and, more particularly, to a semiconductor device, an operating method of the semiconductor device, and a method of manufacturing the semiconductor device.

### 2. Related Art

Recently, as an electronic device is reduced in size, has low power consumption and high performance, and is diversified, a semiconductor device capable of storing information is required for various electronic devices, such as computers and portable communication devices. Accordingly, research is carried out on a semiconductor device capable of storing data by using a characteristic in which the semiconductor device switches between different resistance states depending on a voltage or current applied thereto. Such a semiconductor device includes a resistive random access memory (RRAM), a phase change random access memory (PRAM), a ferroelectric random access memory (FRAM), a magnetic random access memory (MRAM), an E-fuse, or the like.

The type of semiconductor device is classified depending on a material that constitutes a memory cell. In order to improve the transition characteristic of the memory cell, the semiconductor device may perform a specific operation.

For example, a PRAM may perform a firing operation in order to improve the transition characteristic of a phase change material. In the firing operation, in order to improve the transition characteristic of the phase change material, high electrical energy is applied to the phase change material, so that the phase change material has a uniform face-centered cubic (FCC) state.

However, the operation of applying high electrical energy to the memory cell greatly stresses the memory cell, and thus may reduce the durability of the memory cell.

### SUMMARY

In an embodiment, a semiconductor device may include a voltage generation circuit configured to generate a driving voltage in response to a voltage control signal, a row decoder configured to select at least one word line, among a plurality of word lines, in response to a row address signal, and configured to apply the driving voltage to the selected word line, a column decoder configured to select at least one bit line, among a specific bit line and a plurality of bit lines, in response to a column address signal and a control circuit configured to generate the voltage control signal, the row address signal, and the column address signal, and configured to control the column decoder to select the specific bit line and at least one of the plurality of bit lines in a firing operation.

In an embodiment, a semiconductor device may include a voltage generation circuit configured to generate a driving voltage in response to a voltage control signal, a row decoder configured to select at least one word line, among a specific word line and a plurality of word lines, in response to a row address signal, and configured to apply the driving voltage to the selected word line, a column decoder configured to select at least one bit line, among the plurality of bit lines, in response to a column address signal and a control circuit configured to generate the voltage control signal, the row address signal, and the column address signal, and configured to control the row decoder to select the specific word line and at least one of the plurality of word lines in a firing operation.

In an embodiment, an operating method of a semiconductor device may include performing a firing operation that comprises: selecting a specific bit line and at least one of a plurality of bit lines, selecting at least one of a plurality of word lines and applying a driving voltage to the at least one selected word line.

In an embodiment, an operating method of a semiconductor device may include performing a firing operation that comprises: selecting a specific word line and at least one of a plurality of word lines, selecting at least one of a plurality of bit lines, and applying a driving voltage to the selected specific word line and the at least one selected word line.

In an embodiment, a method of manufacturing a semiconductor device may include forming a cell array comprising a plurality of first memory cells and a plurality of second memory cells, each of which has a first variable resistance layer, forming a mask on the cell array and performing an ion implantation process in one direction of the cell array.

In an embodiment, a method of manufacturing a semiconductor device may include forming a first mat and a second mat, each comprising a plurality of first memory cells and a plurality of second memory cells, each memory cell having a first variable resistance layer, forming a mask on each of the first mat and the second mat, forming a trench between the first mat and the second mat and performing an ion implantation process in a direction that is tilted, within the trench; and forming a plurality of contacts within the trench.

### BRIEF DESCRIPTION OF THE DRAWINGS

FIG. 1 illustrates a semiconductor device according to an embodiment of the present disclosure.

FIG. 2 illustrates a semiconductor device according to another embodiment of the present disclosure.

FIG. 3 illustrates a cell array of a semiconductor device according to an embodiment of the present disclosure.

FIGS. 4A and 4B illustrate a method of manufacturing a semiconductor device according to an embodiment of the present disclosure.

FIGS. 5A, 5B, 6A, 6B, 6C, and 7 illustrate a method of manufacturing a semiconductor device according to another embodiment of the present disclosure.

### DETAILED DESCRIPTION

Hereinafter, embodiments according to the technical spirit of the present disclosure are described with reference to the accompanying drawings.

Embodiments of the present disclosure provide a semiconductor device, a manufacturing method, and an operating method, which can reduce stress that is applied to a memory cell in a firing operation.

Embodiments of the present disclosure can improve the durability and reliability of a memory cell by reducing stress that is applied to the memory cell in a firing operation.

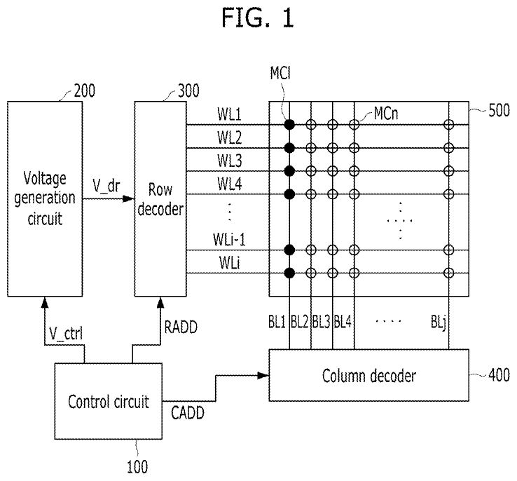

FIG. 1 illustrates a semiconductor device according to an embodiment of the present disclosure.

Referring to FIG. 1, the semiconductor device may include a control circuit 100, a voltage generation circuit 200, a row decoder 300, a column decoder 400, and a cell array 500.

The control circuit 100 may control the voltage generation circuit 200, the row decoder 300, and the column decoder 400. For example, the control circuit 100 may control the voltage generation circuit 200, the row decoder 300, and the column decoder 400 to store data in the cell array 500 or read out data stored in the cell array 500. In this case, the operation of storing data in the cell array 500 may be named a write operation. The operation of reading out data stored in the cell array 500 may be named a read operation. That is, the control circuit 100 may perform a normal operation, such as the write operation or the read operation, by controlling the voltage generation circuit 200, the row decoder 300, and the column decoder 400.

Furthermore, the control circuit 100 may perform a firing operation capable of improving the transition characteristic of memory cells included in the cell array 500 by controlling the voltage generation circuit 200, the row decoder 300, and the column decoder 400. In this case, the cell array 500 may include first memory cells MCn and second memory cells MCI having different characteristics from the first memory cells MCn. For example, the control circuit 100 may perform the firing operation to improve the transition characteristic of the first memory cells MCn.

More specifically, for example, the control circuit 100 may control the voltage generation circuit 200 to generate a driving voltage V_dr having a voltage level, which is used in an operation of the semiconductor device, such as the write operation, the read operation, or the firing operation. Furthermore, the control circuit 100 may control the row decoder 300 and the column decoder 400 in order to selectively turn on the first memory cells MCn and the second memory cells MCI that are included in the cell array 500.

The voltage generation circuit 200 may receive a voltage control signal V_ctrl that is provided by the control circuit 100. The voltage generation circuit 200 may generate the driving voltage V_dr in response to the voltage control signal V_ctrl. For example, the voltage generation circuit 200 may generate the driving voltage V_dr having a voltage level corresponding to the voltage control signal V_ctrl. In this case, the control circuit 100 may generate the voltage control signal V_ctrl to perform an operation of the semiconductor device, such as the write operation, the read operation, or the firing operation. In this case, the voltage generation circuit 200 may generate the driving voltage V_dr having a higher voltage level in the firing operation than in the normal operation, such as the write operation or the read operation.

The row decoder 300 may receive the driving voltage V_dr that is provided by the voltage generation circuit 200 and a row address signal RADD that is provided by the control circuit 100. The row decoder 300 may select at least one of a plurality of word lines WL1 to WLi, and may drive the selected word line with the driving voltage V_dr. For example, the row decoder 300 may select at least one of the plurality of word lines WL1 to WLi in response to the row address signal RADD, and may apply the driving voltage V_dr to the selected word line. The row decoder 300 may provide the selected word line with the driving voltage V_dr as a row selection bias voltage. Furthermore, the row decoder 300 may provide an unselected word line with a row non-selection bias voltage or may float the unselected word line. In this case, voltage levels of the row selection bias voltage and the row non-selection bias voltage may be different from each other.

The column decoder 400 may receive a column address signal CADD that is provided by the control circuit 100. The column decoder 400 may select at least one of a plurality of bit lines BL1 to BLj, including a specific bit line BL1 and bit lines BL2 to BLj, in response to the column address signal CADD. The column decoder 400 may provide a column selection bias voltage to the selected bit line. The column decoder 400 may provide a column non-selection bias voltage to an unselected bit line or float the unselected bit line. Furthermore, the column decoder 400 may provide a specific bias voltage having a preset voltage level to the specific bit line BL1 in the firing operation, and may provide a column non-selection bias voltage to the specific bit line BL1 or float the specific bit line BL1 in the normal operation. In this case, voltage levels of the specific bias voltage, the column selection bias voltage, and the column non-selection bias voltage may be different from one another.

The cell array 500 may include the first memory cells MCn and the second memory cells MCI. In this case, threshold voltages of the second memory cells MCI may each have a lower voltage level than threshold voltages of the first memory cells MCn. The first memory cells MCn and the second memory cells MCI may be electrically connected between the plurality of word lines WL1 to WLi and the plurality of bit lines BL1 to BLj. For example, the first memory cells MCn may be electrically connected between the plurality of word lines WL1 to WLi and the bit lines BL2 to BLj. The second memory cells MCI may be electrically connected between the plurality of word lines WL1 to WLi and the specific bit line BL1. Accordingly, the second memory cells MCI may be aligned in a direction in which the specific bit line BL1 extends.

An operating method of the semiconductor device constructed as described above is described as follows.

First, the normal operation of the semiconductor device, such as the write operation or the read operation, is described.

The control circuit 100 may provide the voltage generation circuit 200 with the voltage control signal V_ctrl, so that the voltage generation circuit 200 generates the driving voltage V_dr having a voltage level corresponding to any one of the normal operations.

In the normal operation, the control circuit 100 may provide the row decoder 300 with the row address signal RADD to thereby select at least one of the plurality of word lines WL1 to WLi.

In the normal operation, the control circuit 100 may provide the column decoder 400 with the column address signal CADD to thereby select at least one of the bit lines BL2 to BLj. In this case, the specific bit line BL1 may be controlled not to be selected in the normal operation.

Accordingly, in the normal operation, the second memory cells MCI may not be selected because the second memory cells MCI are connected to the specific bit line BL1. Instead, at least one of the first memory cells MCn that are connected between the plurality of word lines WL1 to WLi and the bit lines BL2 to BLj may be selected.

The normal operation, such as the write operation or the read operation, may be performed on the selected memory cell that is connected between the selected word line and the selected bit line, among the first memory cells MCn. In the write operation, the selected memory cell may transition to a first state (e.g., a reset state) or a second state (e.g., a set state) based on a voltage difference between the selected word line to which the driving voltage V_dr is applied and the selected bit line or based on a current direction between the selected word line and the selected bit line. Furthermore, in the read operation, the selected memory cell may allow a current corresponding to the transition state (i.e., the first state or the second state) to flow between the selected word line and the selected bit line. Accordingly, the semiconductor device can perform the read operation of determining data that is stored in the selected memory cell by sensing the current and outputting the determined data.

Next, the firing operation of the semiconductor device according to the embodiment of the present disclosure is described.

In the firing operation, the control circuit 100 may provide the voltage generation circuit 200 with the voltage control signal V_ctrl, so that the voltage generation circuit 200 generates the driving voltage V_dr having a higher voltage level than the driving voltage V_dr generated for the normal operation.

In the firing operation, the control circuit 100 may provide the row decoder 300 with the row address signal RADD to thereby select at least one of the plurality of word lines WL1 to WLi.

In the firing operation, the control circuit 100 may provide the column decoder 400 with the column address signal CADD to thereby select the specific bit line BL1 and at least one of the plurality of bit lines BL2 to BLj. In this case, the specific bit line BL1 may always be selected in the firing operation.

Accordingly, in the firing operation, at least one of the second memory cells MCI is always selected because the second memory cells MCI are connected to the specific bit line BL1. That is, in the firing operation, one of the second memory cells MCI may be selected based on a selected word line, among the plurality of word lines WL1 to WLi, because the specific bit line BL1 is always selected. In addition, in the firing operation, at least one of the first memory cells MCn, which are connected between the plurality of word lines WL1 to WLi and the plurality of bit lines BL2 to BLj, may be selected.

As a result, the semiconductor device may select at least one of the first memory cells MCn and at least one of the second memory cells MCI in the firing operation. In this case, the meaning that the first memory cell MCn and the second memory cell MCI are selected may include the meaning that a memory cell that is connected between a selected word line and a selected bit line is turned on based on a difference between voltage levels of the selected word line and the selected bit line. Accordingly, in the firing operation, the semiconductor device can distribute a current flowing into a selected first memory cell to a current path formed by a selected second memory cell.

In the firing operation, the semiconductor device selects a second memory cell having a lower threshold voltage than a first memory cell, along with the first memory cell, and performs the firing operation on the first memory cell. As a result, it is possible to reduce stress that is applied to the first memory cell by distributing a current flowing into the first memory cell to a current path formed by the second memory cell.

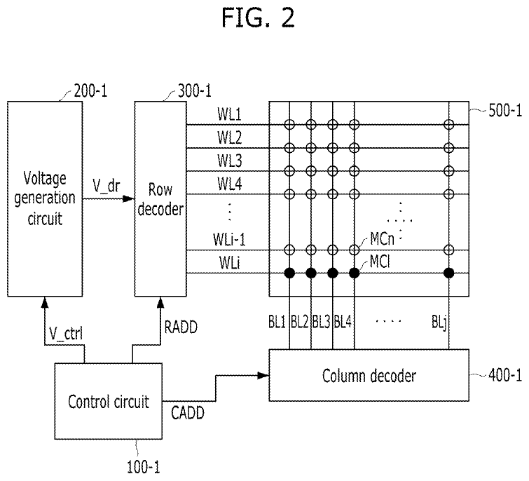

FIG. 2 illustrates a semiconductor device according to another embodiment of the present disclosure.

Referring to FIG. 2, the semiconductor device may include a control circuit 100-1, a voltage generation circuit 200-1, a row decoder 300-1, a column decoder 400-1, and a cell array 500-1.

The control circuit 100-1 may control the voltage generation circuit 200-1, the row decoder 300-1, and the column decoder 400-1. In a manner similar to the control circuit 100 illustrated in FIG. 1, the control circuit 100-1 may control the voltage generation circuit 200-1, the row decoder 300-1, and the column decoder 400-1 to perform a normal operation, such as a write operation or a read operation.

Furthermore, the control circuit 100-1 may perform a firing operation capable of improving the transition characteristic of memory cells MCn included in the cell array 500-1, by controlling the voltage generation circuit 200-1, the row decoder 300-1, and the column decoder 400-1. In this case, the cell array 500-1 may include first memory cells MCn and second memory cells MCI having different characteristics from the first memory cells MCn. For example, the control circuit 100-1 may perform a firing operation capable of improving the transition characteristic of the first memory cells MCn.

In the firing operation, the control circuit 100-1 may control the row decoder 300-1 and the column decoder 400-1 in order to selectively turn on the first memory cells MCn and the second memory cells MCI that are included in the cell array 500-1.

The voltage generation circuit 200-1 may receive a voltage control signal V_ctrl that is provided by the control circuit 100-1. The voltage generation circuit 200-1 may generate a driving voltage V_dr having a voltage level, which is higher in the firing operation than in the normal operation, in response to the voltage control signal V_ctrl.

The row decoder 300-1 may receive the driving voltage V_dr that is provided by the voltage generation circuit 200-1 and a row address signal RADD that is provided by the control circuit 100-1. The row decoder 300-1 may select at least one of word lines WL1 to WLi including a specific word line WLi and a plurality of word lines WL1 to WLi-1, and may drive the selected word line with the driving voltage V_dr. For example, the row decoder 300-1 may select at least one of the word lines WL1 to WLi including the specific word line WLi and the plurality of word lines WL1 to WLi-1 in response to the row address signal RADD, and may apply the driving voltage V_dr to the selected word line. The row decoder 300-1 may provide the driving voltage V_dr to the selected word line as a row selection bias voltage, and may provide a row non-selection bias voltage to an unselected word line.

Furthermore, in the firing operation, the row decoder 300-1 may provide a specific bias voltage having a set voltage level to the specific word line WLi, and, in the normal operation, may provide the row non-selection bias voltage to the specific word line WLi or float the specific word line WLi.

The column decoder 400-1 may receive a column address signal CADD that is provided by the control circuit 100-1. The column decoder 400-1 may select at least one of a plurality of bit lines BL1 to BLj in response to the column address signal CADD. The column decoder 400-1 may provide a column selection bias voltage to the selected bit line, and may provide a column non-selection bias voltage to an unselected bit line or float the unselected bit line.

The cell array 500-1 may include the first memory cells MCn and the second memory cells MCI. In this case, threshold voltages of the second memory cells MCI may each have a lower voltage level than threshold voltages of the first memory cells MCn. The first memory cells MCn and the second memory cells MCI may be electrically connected between the word lines WL1 to WLi and the plurality of bit lines BL1 to BLj. For example, the first memory cells MCn may be electrically connected between the plurality of word lines WL1 to WLi-1 and the plurality of bit lines BL1 to BLj. The second memory cells MCI may be electrically connected between the specific word line WLi and the plurality of bit lines BL1 to BLj. Accordingly, the second memory cells MCI may be aligned in a direction in which the specific word line WLi extends.

An operating method of the semiconductor device shown in FIG. 2 is described as follows.

First, the normal operation of the semiconductor device, such as the write operation or the read operation, is described.

The control circuit 100-1 may provide the voltage generation circuit 200-1 with the voltage control signal V_ctrl, so that the voltage generation circuit 200-1 generates the driving voltage V_dr having a voltage level corresponding to any one of normal operations.

In the normal operation, the control circuit 100-1 may provide the row decoder 300-1 with the row address signal RADD capable of selecting at least one of the plurality of word lines WL1 to WLi-1 except the specific word line WLi. In this case, the specific word line WLi may not be selected in the normal operation.

In the normal operation, the control circuit 100-1 may provide the column decoder 400-1 with the column address signal CADD capable of selecting at least one of the plurality of bit lines BL1 to BLj.

Accordingly, in the normal operation, the second memory cells MCI may not be selected because the second memory cells MCI are connected to the specific word line WLi that is not selected. Instead, at least one of the first memory cells MCn connected between the plurality of word lines WL1 to WLi-1 and the plurality of bit lines BL1 to BLj may be selected.

The normal operation, such as the write operation or the read operation, may be performed on at least one memory cell that is connected between a selected word line and a selected bit line, among the first memory cells MCn. In this case, in the write operation, the selected memory cell may transition to a first state (e.g., a reset state) or a second state (e.g., a set state) based either on a voltage difference between the selected word line, to which the driving voltage V_dr is applied, and the selected bit line, or on the direction of a current flowing between the selected word line and the selected bit line. In the read operation, the first memory cells MCn may allow a current corresponding to the transition state (i.e., the first state or the second state) to flow between the selected word line and the selected bit line. Accordingly, the semiconductor device can perform the read operation for determining data that is stored in the selected memory cell by sensing the current and outputting the determined data.

Next, the firing operation of the semiconductor device shown in FIG. 2 is described as follows.

In the firing operation, the control circuit 100-1 may provide the voltage generation circuit 200-1 with the voltage control signal V_ctrl, so that the voltage generation circuit 200-1 generates the driving voltage V_dr having a higher voltage level than the driving voltage V_dr generated in the normal operation.

In the firing operation, the control circuit 100-1 may provide the row address signal RADD to the row decoder 300-1 to select the specific word line WLi and at least one of the plurality of word lines WL1 to WLi-1. In this case, the specific word line WLi may always be selected in the firing operation.

In the firing operation, the control circuit 100-1 may provide the column address signal CADD to the column decoder 400-1 to select at least one of the plurality of bit lines BL1 to BLj.

Accordingly, in the firing operation, at least one of the second memory cells MCI may always be selected because the second memory cells MCI are connected to the specific word line WLi. That is, in the firing operation, at least one of the second memory cells MCI may be selected based on a selected bit line, among the plurality of bit lines BL1 to BLj, because the specific word line WLi is always selected. In addition, at least one of the first memory cells MCn connected between the plurality of word lines WL1 to WLi-1 and the plurality of bit lines BL1 to BLj may be selected.

As a result, the semiconductor device can select at least one of the first memory cells MCn and at least one of the second memory cells MCI in the firing operation. Accordingly, in the firing operation, the semiconductor device can distribute a current flowing into a selected first memory cell to a current path formed by a selected second memory cell.

In the firing operation, the semiconductor device selects a second memory cell having a lower threshold voltage than a first memory cell, along with the first memory cell, and performs the firing operation on the first memory cell. Therefore, it is possible to reduce stress that is applied to the first memory cell by distributing a current flowing into the first memory cell to a current path formed by the second memory cell.

As illustrated in FIGS. 1 and 2, the semiconductor device according to the embodiment of the present disclosure may include the cell array 500 or 500-1 that includes the first memory cell MCn, which is selected in the normal operation and the firing operation, and the second memory cell MCI, which is selected only in the firing operation.

The second memory cell MCI that is selected only in the firing operation may have a lower threshold voltage than the first memory cell MCn, and may be connected to a specific access line (e.g., the bit line BL1 or the word line WLi). In this case, access lines may include a bit line and a word line. The specific access line may mean one line, among the bit line and the word line.

More specifically, the second memory cell MCI having a lower threshold voltage than the first memory cell MCn may be connected to a word line or a bit line that is disposed at the outermost part of each of the cell arrays 500 and 500-1.

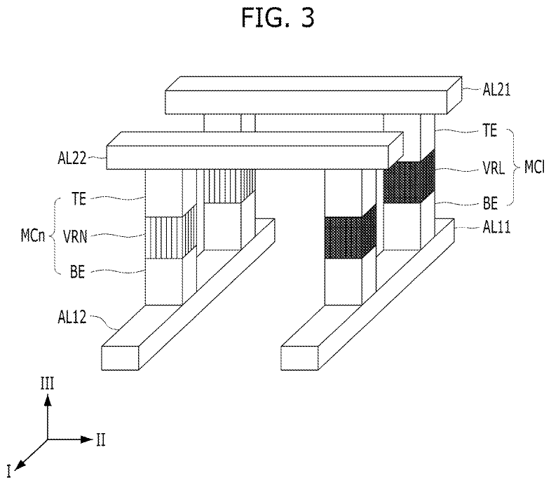

FIG. 3 illustrates a cell array of a semiconductor device according to an embodiment of the present disclosure.

The cell array of the semiconductor device may have a three-dimensional cross-point array structure. The cell array may include access lines disposed on different layers, and may include memory cells disposed where access lines extending in different directions intersect.

Referring to FIG. 3, the cell array may include at least one first memory cell MCn and at least one second memory cell MCI. In this case, the second memory cell MCI may be a memory cell having a lower threshold voltage than the first memory cell MCn. A first direction I and a second direction II may intersect. A third direction III may be orthogonal to the plane that is defined by the first direction I and the second direction II.

The first memory cell MCn may be disposed where a first access line AL12, which extends in the first direction I, intersects with a second access line AL22 that extends in the second direction II. For example, the first memory cell MCn may be electrically connected between the first access line AL12 and the second access line AL22. In this case, first access lines AL11 and AL12 that extend in the first direction I, and second access lines A21 and AL22 that extend in the second direction II, may be stacked in the third direction III.

The second memory cell MCI may be disposed where the first access line AL11, which extends in the first direction I, intersects with the second access line AL21 that extends in the second direction II. For example, the second memory cell MCI may be electrically connected between the first access line AL11 and the second access line AL21. In this case, the first access line AL11 to which the second memory cell MCI is connected may be a specific access line disposed at the outermost part of the cell array, among the first access lines AL12 and AL11 that are included in the cell array and that extend in the first direction I. Accordingly, the second memory cells MCI may be disposed where the second access lines AL21 and AL22 intersect with the specific access line AL11. For example, the second memory cells MCI may be aligned at the outermost part of the cell array in the first direction I.

The first memory cells MCn may be disposed where at least one first access line, e.g., the first access line AL12, except the specific access line AL11, among the first access lines AL11 and AL12, intersect with the second access lines AL21 and AL22. For example, the first memory cells MCn may be aligned in the first direction I and the second direction II.

As an embodiment, the first access lines AL11 and AL12 that extend in the first direction I may be word lines, and the second access lines AL21 and AL22 that extend in the second direction II may be bit lines. Alternatively, the first access lines AL11 and AL12 that extend in the first direction I may be bit lines, and the second access lines AL21 and AL22 that extend in the second direction II may be word lines. The first access lines and the second access lines may include a conductive material, such as polysilicon or a metal.

Each of the first memory cell MCn and the second memory cell MCI may include a bottom electrode BE, each of variable resistance layers VRN and VRL, and a top electrode TE that are stacked in the third direction III. For example, the first memory cell MCn may include the bottom electrode BE, the first variable resistance layer VRN, and the top electrode TE. The second memory cell MCI may include the bottom electrode BE, the second variable resistance layer VRL, and the top electrode TE. In this case, the first and second variable resistance layers VRN and VRL may each include a variable resistance material or a phase change material. The second variable resistance layer VRL may be formed by doping a specific material into the first variable resistance layer VRN, so that the second variable resistance layer VRL has a lower resistance level than the first variable resistance layer VRN. Therefore, the material that is doped into the first variable resistance layer VRN in order to form the second variable resistance layer VRL may be a material capable of lowering the resistance level of the first variable resistance layer VRN.

For example, if the first variable resistance layer VRN includes a chalcogenide material such as Ge-Sb-Te (GST) that is a phase change material, the second variable resistance layer VRL may be formed by doping some of GST into the first variable resistance layer VRN. Accordingly, the second memory cell MCI may have a lower threshold voltage than the first memory cell MCn. As a result, a selected second memory cell MCI can flow a larger amount of current therethrough than a selected first memory cell MCn. For example, the first memory cell MCn may be named a normal memory cell, and the second memory cell MCI may be named a leaky memory cell.

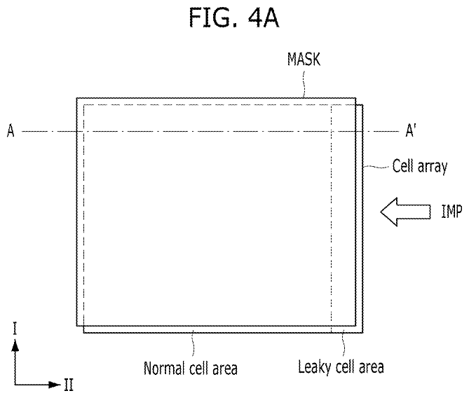

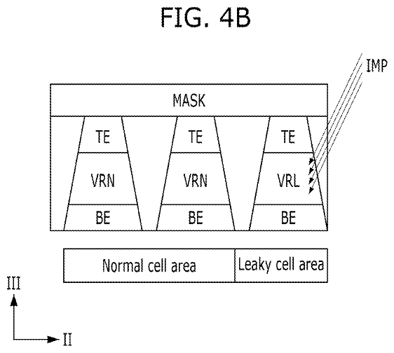

FIGS. 4A and 4B illustrate a method of manufacturing a semiconductor device according to an embodiment of the present disclosure. FIG. 4B may be a cross-sectional view taken along line A-A′ in FIG. 4A.

Referring to FIGS. 4A and 4B, a mask may be provided on a cell array. An ion implantation process IMP may be performed in one direction of the cell array to dope a specific material to a part of the cell array. In this case, the cell array may be divided into a leaky cell area, which includes memory cells into which the specific material has been doped, and a normal cell area, which includes memory cells that have not been doped with the specific material.

For example, the normal cell area includes memory cells, each including a bottom electrode BE, a first variable resistance layer VRN, and a top electrode TE. The leaky cell area includes memory cells, each including a bottom electrode BE, a second variable resistance layer VRL, and a top electrode TE. The second variable resistance layer VRL may be formed by doping the specific material into the first variable resistance layer VRN through the ion implantation process IMP after the first variable resistance layer VRN is formed. In this case, the second variable resistance layer VRL may have a lower resistance level than the first variable resistance layer VRN. An ion implantation angle in the ion implantation process IMP may be an angle that is tilted from a third direction III as shown in FIG. 4B.

Accordingly, memory cells, which are aligned in a first direction I and each include the second variable resistance layer VRL, may be formed in the outermost area of the cell array.

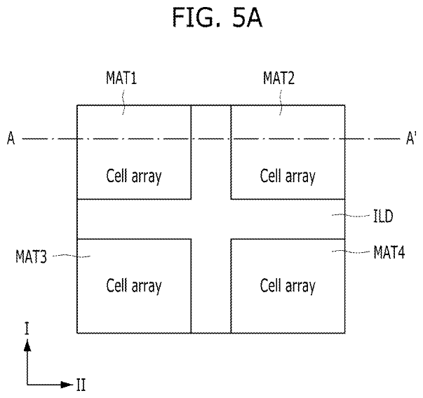

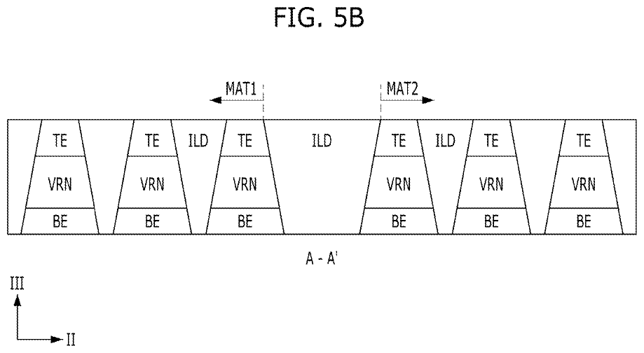

FIGS. 5A, 5B, 6A, 6B, 6C, and 7 illustrate a method of manufacturing a semiconductor device according to another embodiment of the present disclosure.

FIG. 5B shows a cross-sectional view taken along line A-A′ in FIG. 5A.

Referring to FIGS. 5A and 5B, a cell array that is divided into first to fourth mats MAT1, MAT2, MAT3, and MAT4 may be formed. In this case, an insulating layer ILD may be formed between the four mats MAT1, MAT2, MAT3, and MAT4 and/or between memory cells in each mat. For example, the insulating layer ILD may be formed between the first mat MAT1 and the second mat MAT2. A memory cell that is included in each of the first mat MAT1 and the second mat MAT2 may include a bottom electrode BE, a first variable resistance layer VRN, and a top electrode TE that are stacked in a third direction III. Furthermore, the insulating layer ILD may be formed between memory cells that are included in each of the first mat MAT1 and the second mat MAT2.

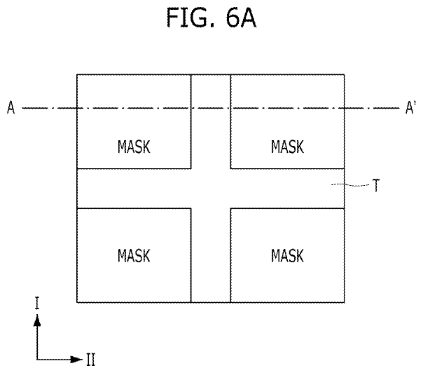

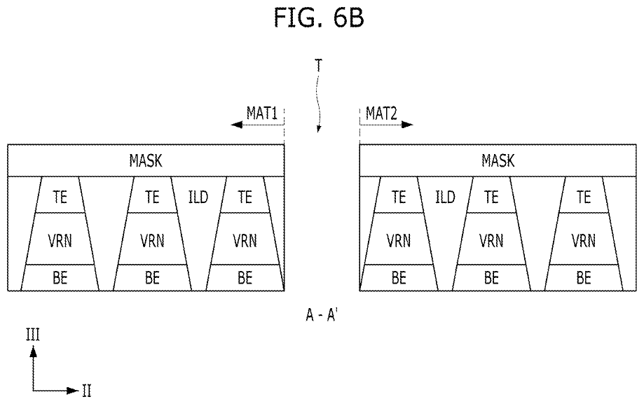

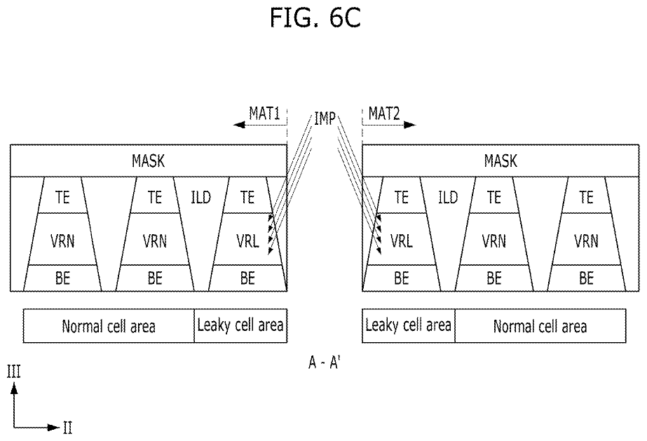

FIG. 6B shows a cross section taken along line A-A′ in FIG. 6A. FIG. 6C may be a cross-sectional view for describing a process subsequent to FIG. 6B.

Referring to FIGS. 6A, 6B, and 6C, masks MASK may be provided on mat MAT1, MAT2, MAT3, and MAT4, respectively. Thereafter, a trench T may be formed by removing an insulating layer ILD that is disposed between the masks MASK respectively formed on the first to fourth mats MAT1, MAT2, MAT3, and MAT4 through an etch process. The trench T may have a cross (+) form that extends in first and second directions I and II, and may have a depth that extends in a third direction III. The trench T may have a depth that exposes a top electrode TE, a first variable resistance layer VRN, and a bottom electrode BE. These components constitute a memory cell within each of the mats MAT1, MAT2, MAT3, and MAT4.

Thereafter, an ion implantation process IMP may be performed at an angle that is tilted from the third direction III within a part of the trench T that extends in the first direction I. Therefore, a second variable resistance layer VRL may be formed by doping a specific material into the first variable resistance layer VRN at a location that is closest to the trench T.

Accordingly, each of the first mat MAT1 and the second mat MAT2 may include a leaky cell area including memory cells, each including the second variable resistance layer VRL, and a normal cell area including memory cells, each including the first variable resistance layer VRN.

As a result, each of the first to fourth mats MAT1, MAT2, MAT3, and MAT4 may include the leaky cell area and the normal cell area.

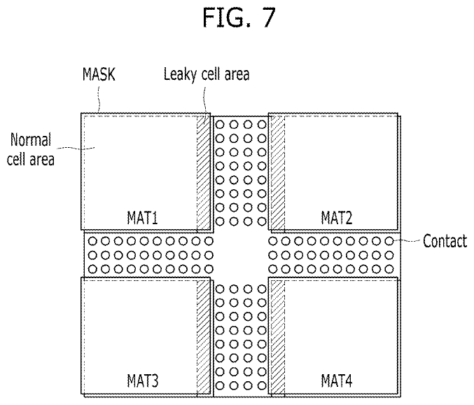

Referring to FIG. 7, the first mat MAT1 may include the normal cell area and the leaky cell area. The leaky cell area extends in the first direction I at a location closest to the second mat MAT2. That is, in the first mat MAT1, the leaky cell area extends in the first direction I at the outermost part of the first mat MAT1, which is closest to the second mat MAT2.

The second mat MAT2 may include the normal cell area and the leaky cell area. The leaky cell area extends in the first direction I at a location closest to the first mat MAT1. That is, in the second mat MAT2, the leaky cell area extends in the first direction I at the outermost part of the second mat MAT2, which is closest to the first mat MAT1.

The third mat MAT3 may include the normal cell area and the leaky cell area. The leaky cell area extends in the first direction I at a location closest to the fourth mat MAT4. That is, in the third mat MAT3, the leaky cell area extends in the first direction I at the outermost part of the third mat MAT3, which is closest to the fourth mat MAT4.

The fourth mat MAT4 may include the normal cell area and the leaky cell area. The leaky cell area extends in the first direction I at a location closest to the third mat MAT3. That is, in the fourth mat MAT4, the leaky cell area extends in the first direction I at the outermost part of the fourth mat MAT4, which is closest to the third mat MAT3.

Thereafter, a plurality of contacts may be formed within the trench T. The plurality of contacts may be connected to access lines of the mats MAT1, MAT2, MAT3, and MAT4, respectively, in a subsequent process.

As described above, in the method of manufacturing the semiconductor device according to the embodiment of the present disclosure, the leaky cell area that extends in a specific direction may be formed at the outermost part of a cell array. A memory cell in the leaky cell area may have a lower resistance level than a memory cell in a normal cell area.

Although the embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. A semiconductor device comprising:
a voltage generation circuit configured to generate a driving voltage in response to a voltage control signal;
a row decoder configured to select at least one word line, among a plurality of word lines, in response to a row address signal, and configured to apply the driving voltage to the selected word line;
a column decoder configured to select at least one bit line, among a specific bit line and a plurality of bit lines, in response to a column address signal; and
a control circuit configured to generate the voltage control signal, the row address signal, and the column address signal, and configured to control the column decoder to select the specific bit line and at least one of the plurality of bit lines in a firing operation.

2. The semiconductor device of claim 1, wherein the control circuit generates the column address signal so that the column decoder selects at least one of the plurality of bit lines in a normal operation.

3. The semiconductor device of claim 2, further comprising a cell array comprising first memory cells connected to the plurality of bit lines and second memory cells connected to the specific bit line.

4. The semiconductor device of claim 3, wherein threshold voltages of the second memory cells each have a lower voltage level than threshold voltages of the first memory cells.

5. A semiconductor device comprising:
a voltage generation circuit configured to generate a driving voltage in response to a voltage control signal;
a row decoder configured to select at least one word line, among a specific word line and a plurality of word lines, in response to a row address signal, and configured to apply the driving voltage to the selected word line;
a column decoder configured to select at least one bit line, among the plurality of bit lines, in response to a column address signal; and
a control circuit configured to generate the voltage control signal, the row address signal, and the column address signal, and configured to control the row decoder to select the specific word line and at least one of the plurality of word lines in a firing operation.

6. The semiconductor device of claim 5, wherein the control circuit generates the row address signal to select at least one of the plurality of bit lines in a normal operation.

7. The semiconductor device of claim 6, further comprising a cell array comprising first memory cells connected to the plurality of word lines and second memory cells connected to the specific word line.

8. The semiconductor device of claim 7, wherein threshold voltages of the second memory cells each have a lower voltage level than threshold voltages of the first memory cells.

9. An operating method of a semiconductor device, the method comprising:
performing a firing operation that comprises:
selecting a specific bit line and at least one of a plurality of bit lines;
selecting at least one of a plurality of word lines; and
applying a driving voltage to the at least one selected word line.

10. The operating method of claim 9, wherein memory cells connected to the specific bit line each have a lower threshold voltage than memory cells connected to the plurality of bit lines.

11. The operating method of claim 9, further comprising:
performing a normal operation that comprises:
selecting at least one of the plurality of bit lines without selecting the specific bit line.

12. The operating method of claim 9, wherein the applying of the driving voltage comprises applying, to the selected word line, the driving voltage having a higher voltage level than that used in a normal operation.

13. An operating method of a semiconductor device, comprising:
performing a firing operation that comprises:
selecting a specific word line and at least one of a plurality of word lines;
selecting at least one of a plurality of bit lines; and
applying a driving voltage to the selected specific word line and the at least one selected word line.

14. The operating method of claim 13, wherein memory cells connected to the specific word line each have a lower threshold voltage than memory cells connected to the plurality of word lines.

15. The operating method of claim 13, further comprising:
performing a normal operation that comprises:
selecting at least one of the plurality of word lines in a normal operation without selecting the specific word line.

16. The operating method of claim 13, wherein the applying of the driving voltage comprises applying, to the selected specific word line and the at least one selected word line, the driving voltage having a higher voltage level than that used in a normal operation.

17. A method of manufacturing a semiconductor device, the method comprising:
forming a cell array comprising a plurality of first memory cells and a plurality of second memory cells, each of which has a first variable resistance layer;
forming a mask on the cell array; and
performing an ion implantation process in one direction of the cell array.

18. The method of claim 17, wherein the performing of the ion implantation process comprises forming a second variable resistance layer by doping, into the first variable resistance layer, a material that lowers a resistance level of the first variable resistance layer.

19. The method of claim 18, wherein the ion implantation process is performed with an angle that is tilted from a vertical direction.

20. The method of claim 18, wherein the plurality of first memory cells each having the second variable resistance layer are disposed at an outermost part of the cell array.

21. A method of manufacturing a semiconductor device, comprising:
forming a first mat and a second mat, each comprising a plurality of first memory cells and a plurality of second memory cells, each memory cell having a first variable resistance layer;
forming a mask on each of the first mat and the second mat;
forming a trench between the first mat and the second mat; and
performing an ion implantation process in a direction that is tilted, within the trench; and forming a plurality of contacts within the trench.

22. The method of claim 21, wherein the performing of the ion implantation process comprises forming a second variable resistance layer by doping, into the first variable resistance layer, a material that lowers a resistance level of the first variable resistance layer.

23. The method of claim 22, wherein the plurality of first memory cells each having the second variable resistance layer are disposed at an outermost part of each of the first and second mats, which is closest to the trench.
